(19) United States
(12) Patent Application Publication
(10) Pub. No.: US 2012/0194135 A1
(43) Pub. Date: Aug. 2, 2012

(54) BATTERY VOLTAGE MONITORING APPARATUS

(75) Inventor: Tomomichi MIZOGUCHI, Nagoya (JP)

(73) Assignee: DENSO CORPORATION, Kariya-city (JP)

(21) Appl. No.: 13/363,682

(22) Filed: Feb. 1, 2012

(30) Foreign Application Priority Data
Feb. 1, 2011 (JP) 2011-019734

(51) Int. Cl. H02J 7/00; G01R 31/36

(52) U.S. Cl. 320/118; 324/434

(57) ABSTRACT

The battery voltage monitoring apparatus has a structure in which, for each adjacent two of battery cells, the positive electrode of the battery cell on the higher voltage side and the negative electrode of the battery cell on the lower voltage side are commonly connected to a corresponding one of common terminals provided in an RC filter circuit. The common terminal is branched into a first branch connected to one end of a first resistor and a second branch connected to one end of a second resistor, the first resistor being connected to a corresponding one of positive side detection terminals at the other end thereof, the second resistor being connected to a corresponding one of negative side detection terminals at the other end thereof. A capacitor is connected across a corresponding one of pairs of the positive side and negative side detection terminals.

This application claims priority to Japanese Patent Application No. 2011-19734 filed on Feb. 1, 2011, the entire contents of which are hereby incorporated by reference.

### BACKGROUND OF THE INVENTION

1. Field of the Invention

The present disclosure relates to a battery voltage monitoring apparatus including an RC filter circuit.

2. Description of Related Art

There is known a battery voltage monitoring apparatus capable of detecting a cell voltage of each of battery cells constituting a battery pack, as described, for example, in Japanese Patent Application Laid-open No. 2007-10580. The battery voltage monitoring apparatus described in this patent document is connected with positive and negative terminals of each battery cell to detect the cell voltage of each battery cell.

Generally, as shown in FIG. 10, such a battery voltage monitoring apparatus is provided with a filter circuit as a noise countermeasure. The battery voltage monitoring apparatus shown in FIG. 10 includes a filter circuit 130 and a battery voltage measuring apparatus 120. The filter circuit 130 is disposed between the positive and negative electrodes of respective battery cells 110 constituting a battery pack 100 and the battery voltage measuring apparatus 120.

A wire is connected between each of the positive and negative electrodes of each battery cell 110 and the battery voltage measuring apparatus 120 through the filter circuit 130. For each adjacent two of the battery cells 110, the wire connected to the negative electrode of one battery cell 110 is also used as the wire connected to the positive electrode of the other battery cell 110 except the battery cell 110 on the highest voltage side and the battery cell 110 on the lowest voltage side.

The filter circuit 130 includes resistors 140 respectively interposed in the wires connected between the electrodes of the respective battery cells 110 and input terminals of the battery voltage measuring apparatus 120, and capacitors 150 each connected across adjacent two of the input terminals. One of the resistors 140 and a corresponding one of the capacitors 150 constitute an RC filter as a low-pass filter for each one of the battery cells 110.

When a current pathway across n (n being a positive integer) neighboring battery cells 110 is referred to as “pathway n”, since the pathway n is constituted of two resistors 140 and n series-connected capacitors 150, the transfer function Gain of the pathway n is given by the expression of Gain=1/{1+2π·(2R)·(C/n)}, where R is a resistance of the resistor 140, C is a capacitance of the capacitor 150, and f is a cut-off frequency of the pathway n. In this expression, when (2R)−(C/n)=Tn, since Tn is proportional to (1/n), and fn=(1/Tn), the cut-off frequency fn is in proportion to n.

FIG. 11 is a diagram showing variation of the cut-off frequency fn for various values of n. In FIG. 11, f1 indicates the cut-off frequency of pathway 1, f2 indicates the cut-off frequency of pathway 2, f3 indicates the cut-off frequency of pathway 3, and f12 indicates the cut-off frequency of pathway 12. As seen from FIG. 11, the cut-off frequency increases with the increase of n, that is, with the increase of the number of the battery cells 110 or the capacitors 150 connected in series. For example, when the battery pack 100 is constituted of twelve battery cells 110 as shown in FIG. 10, the maximum cut-off frequency is twelve times as high as the minimum cut-off frequency. Hence, the conventional battery voltage monitoring apparatus as described above has a problem in that the different pathways have different cut-off frequencies.

### SUMMARY

An exemplary embodiment provides a battery voltage monitoring apparatus comprising:

pairs of positive side and negative side detection terminals provided respectively corresponding to positive and negative electrodes of battery cells connected in series to form a battery pack;

an RC filter circuit interposed between the positive and negative electrodes of the battery cells and the pairs of the positive side and negative side detection terminals; and

a detection means for detecting a cell voltage of each of the battery cells applied across a corresponding one of the pairs of the positive side and negative side detection terminals,

wherein

for each adjacent two of the battery cells, the positive electrode of the battery cell on the higher voltage side and the negative electrode of the battery cell on the lower voltage side are commonly connected to a common terminal provided in the RC filter circuit,

the common terminal is branched into a first branch connected to one end of a first resistor as a component of the RC filter circuit and a second branch connected to one end of a second resistor as a component of the RC filter circuit, the first resistor being connected to a corresponding one of the positive side detection terminals at the other end thereof, the second resistor being connected to a corresponding one of the negative side detection terminals at the other end thereof, and

a capacitor is connected across a corresponding one of the pairs of the positive side and negative side detection terminals as a component of the RC filter circuit.

According to the exemplary embodiment, there is provided a battery voltage monitoring apparatus of the type including an RC filter circuit disposed between a battery pack constituted of battery cells connected in series and a battery voltage detecting circuit thereof, the battery voltage monitoring apparatus having a structure to reduce variation in cut-off frequency among respective current pathways through which discharge currents of the respective battery cell flow.

Other advantages and features of the exemplary embodiment will become apparent from the following description including the drawings and claims.

### BRIEF DESCRIPTION OF THE DRAWINGS

In the accompanying drawings:

FIG. 1 is a diagram showing the overall structure of a battery voltage monitoring system including a battery voltage monitoring apparatus according to a first embodiment of the invention;

FIG. 2 is a diagram for explaining the filtering characteristic of an RC filter circuit included in the battery voltage monitoring apparatus shown in FIG. 1;

FIG. 3 is a diagram for explaining IC's internal equalization by an internal equalizing circuit included in the battery voltage monitoring apparatus shown in FIG. 1;

FIG. 4 is a diagram for explaining IC's external equalization by an external equalizing circuit included in the battery voltage monitoring apparatus shown in FIG. 1;

FIG. 5 is a diagram for explaining wire breakage detection in the battery voltage monitoring system shown in FIG. 1;

FIG. 6A is a table showing the cell voltages when there is no wire breakage in the wires L1 to L5 shown in FIG. 5; FIG. 6B is a table showing the cell voltages when there is a wire breakage in the wire L2 shown in FIG. 5; FIG. 6C is a table showing the cell voltages when there is a wire breakage in the wire L0 shown in FIG. 5;

FIG. 7 is a diagram showing the overall structure of a battery voltage monitoring system including a battery voltage monitoring apparatus according to a second embodiment of the invention;

FIG. 8 is a diagram for explaining IC's internal equalization by an internal equalizing circuit included in the battery voltage monitoring apparatus shown in FIG. 7;

FIG. 9 is a diagram for explaining IC's external equalization by an external equalizing circuit included in the battery voltage monitoring apparatus shown in FIG. 7;

FIG. 10 is a diagram showing the structure of a conventional battery voltage monitoring apparatus; and

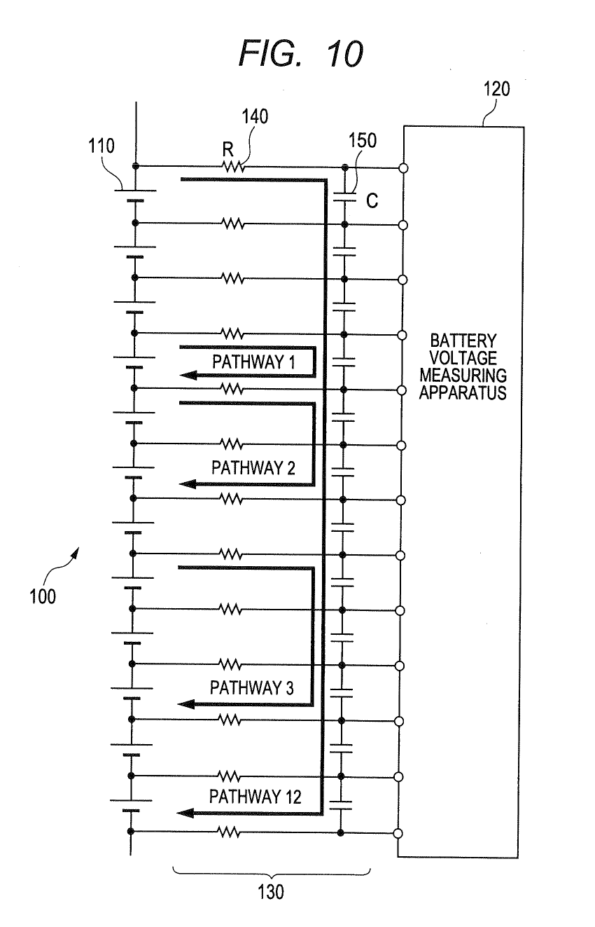

FIG. 11 is a diagram showing variation of the cut-off frequency of the filter circuit for different current pathways shown in FIG. 10.

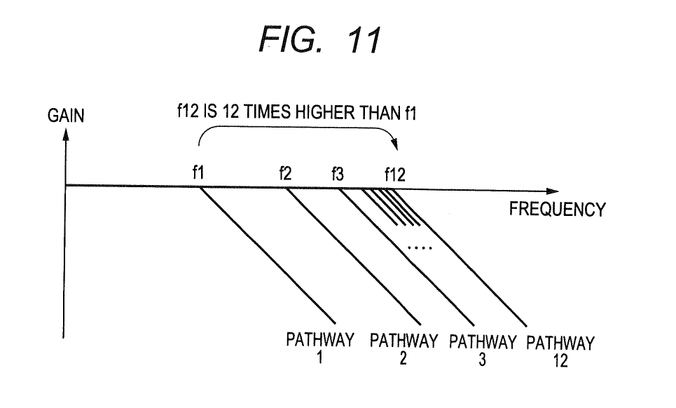

### PREFERRED EMBODIMENTS OF THE INVENTION

In the following description, the same or equivalent parts are indicated by the same reference numerals or characters.

### First Embodiment

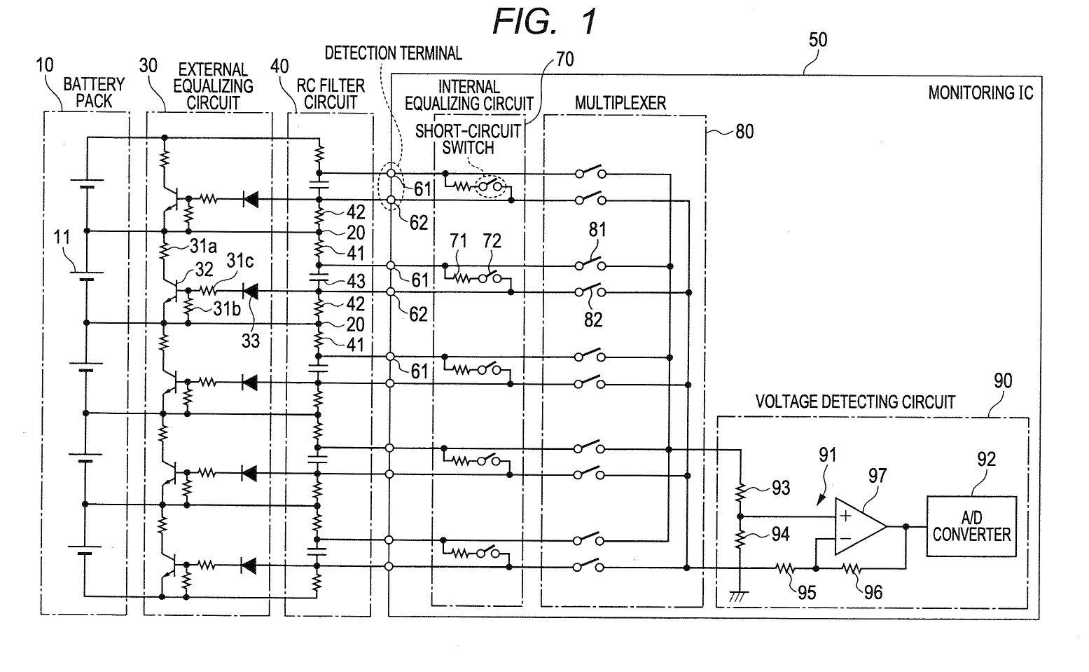

FIG. 1 is a diagram showing the overall structure of a battery voltage monitoring system including a battery voltage monitoring apparatus according to a first embodiment of the invention. The battery voltage monitoring system includes the battery voltage monitoring apparatus and a battery pack 10.

The battery pack 10 is constituted of a plurality of (five in this embodiment) battery cells 11 connected in series. Rechargeable lithium-ion batteries are used as the battery cells 11. The battery pack 10 is mounted on a hybrid vehicle or an electric vehicle as a power source for electrical loads such as an inverter or a motor, or a power source for electronic devices.

For each adjacent two of the battery cells 11, the wire connected between the negative electrode of one battery cell 11 and one of common terminals 20 provided in a later-described RC filter circuit 40 is used also as the wire connected between the positive electrode of the other battery cell 11 and another one of the common terminals 20, except the battery cell 11 on the highest voltage side and the battery cell 11 on the lowest voltage side. That is, each common terminal 20 is connected to the electrode of adjacent two of the battery cells 11 by a single wire.

The battery voltage monitoring apparatus is constituted of an external equalizing circuit 30, the RC filter circuit 40, a monitoring IC 50 and a microcomputer (not shown).

The external equalizing circuit 30 is a circuit for equalizing the cell voltages of the battery cells 11 by discharging the battery cells 11 to be discharged. The external equalizing circuit 30 includes, for each battery cell 11, resistors 31a and 31b, an NPN transistor 32 and a diode 33.

The resistor 31a is connected at one end thereof to the positive terminal of the battery cell 11 (or one of corresponding two of the common terminals 20 disposed in the RC filter circuit 40), and connected to the collector of the transistor 32 at the other end thereof. The emitter of the transistor 32 is connected to the negative terminal of the battery cell 11 (or the other of the corresponding two of the common terminals 20). The resistor 31b is connected between the base and emitter of the transistor 32. The resistor 31c and the diode 33 are connected in series between the base of the transistor 32 and a node between a later-described resistor 41 and a later-described capacitance 43 of the RC filter circuit 40. More specifically, the cathode of the diode 33 is connected to one end of the resistor 31c which is connected to the base of the transistor 32 at the other end thereof, and the anode of the diode 33 is connected to the above node. When a current is passed to the base of the transistor 32 through the diode 33 to turn on the transistor 32, a discharge current flows between the positive and negative electrodes of the battery cell 11 through the resistor 31a and the transistor 32.

The RC filter circuit 40 is a noise eliminating circuit disposed between the positive and negative terminals of the respective battery cells 11 and a plurality of paired detection terminals 61 and 62 provided in the monitoring IC. More specifically, the RC filter circuit 40 is a low-pass filter disposed between the external equalizing circuit 30 and the respective pairs of the detection terminals 61 and 62 of the monitoring IC 50. The pairs of the detection terminals 61 and 62 are provided for the pairs of the positive and negative electrodes of the battery cells 11 on a one-to-one basis.

The RC filter circuit 40 includes, for each battery cell 11, resistors 41 and 42 and a capacitor 43. The resistor 41 is connected to one of two branches of the common terminal 20 connected to the positive terminal of the corresponding battery cell 11. The resistor 42 is connected to one of two branches of the common terminal 20 connected to the negative terminal of the corresponding battery cell 11. The capacitor 43 is connected between the resistors 41 and 42. The capacitor 43 is connected also to the detection terminal 61 at one terminal thereof connected to the resistor 41, and to the detection terminal 62 at the other terminal thereof connected to the resistor 42.

In other words, the common terminal 20 connected to the corresponding battery cell 11 is branched into two to be connected with the resistor 41 and the resistor 42, respectively. These resistors 41 and 42 are connected to the paired detection terminals 61 and 62, respectively. The capacitor 43 is connected between the paired detection terminals 61 and 62.

In the RC filter circuit 40 having the above described structure, the resistors 41 and 42 are not interposed in the wire connected between the electrodes of the battery cell and the common terminal 20, but respectively connected to the branches of the common terminal 20. The anode of the diode 33 of the external equalizing circuit 30 is connected between the capacitor 43 and the resistor 42.

The common terminals 20 are shown as being provided in the RC filter circuit 40 in FIG. 1. However, they are actually disposed on the side closer to the battery pack 10 than the external equalizing circuit 30, because the battery voltage monitoring apparatus is implemented as a single electronic circuit board. It is a matter of course that when the common terminals 20 are disposed on the edge side of the electronic circuit board, each of the common terminals 20 is branched into two to be connected with the resistors 41 and 42, respectively.

The monitoring IC 50 is a device for detecting the cell voltage applied between the paired detection terminals 61 and 62 provided for each of the battery cells 11. The monitoring IC 50 includes the pairs of the detection terminals 61 and 62, an internal equalizing circuit 70, a multiplexer 80 and a voltage detecting circuit 90.

The internal equalizing circuit 70 is a circuit for equalizing the cell voltages of the respective battery cells 11 by passing a discharge current from each of the battery cells 11 to the inside of the monitoring IC 50. The internal equalizing circuit 70 includes, for each of the battery cells 11, a resistor 71 and a short-circuit switch 72 connected in series.

The resistor 71 is connected to the detection terminal 61, while the resistor 72 is connected to the detection terminal 62. Accordingly, the short-circuit switch 72 is connected between the paired detection terminals 61 and 62.

The multiplexer 80 is a group of switches to enable connecting any one of the battery cells 11 constituting the battery pack 10 to the voltage detecting circuit 90. The multiplexer 80 includes, for each of the battery cells 11, a positive-electrode side switch 81 connected to the detection terminal 61 corresponding to the positive terminal of the battery cell 11 at one contact thereof, and a negative-electrode side switch 82 connected to the detection terminal 62 corresponding to the negative terminal of the battery cell 11 at one contact thereof.

Each of the switches 81 and 82 are constituted of a transistor. To detect the cell voltage of the battery cell 11, the positive-electrode side switch 81 and the negative-electrode side switch 82 corresponding to this battery cell 11 are turned on by a switch selecting circuit (not shown).

The voltage detecting circuit 90 is a circuit for amplifying the cell voltage of the battery cell 11 selected by the multiplexer 80 and measuring the amplified cell voltage. The voltage detecting circuit 90 includes a differential amplifier circuit 91 and an A/D converter 92.

The differential amplifier circuit 91, which is connected with the other ends of the switches 81 and 82 of the multiplexer 80, is constituted of resistors 93 to 96 and an operational amplifier 97. The resistor 93 is connected to the other ends of the positive-electrode side switches 81. The resistor 94 is connected between the resistor 94 and the ground.

The connection node between the resistors 93 and 94 is connected to the non-inverting input terminal of the operational amplifier 97. The resistor 95 is connected to the other ends of the positive-electrode side switches 82 of the multiplexer 80. The resistor 96 is connected between the resistor 95 and the output terminal of the operational amplifier 97. The connection node between the resistors 95 and 96 is connected to the inverting input terminal of the operational amplifier 97.
The output terminal of the operational amplifier 97 is connected to the input terminal of the A/D converter 92.

The A/D converter 92 is a circuit for measuring the cell voltage amplified by the differential amplifier circuit 91 in accordance with a command received from the microcomputer. The A/D converter 92 converts the measured cell voltage into a digital signal, and outputs it to the microcomputer.

The microcomputer, which includes a CPU, a ROM, an EEPROM and a RAM, executes programs stored in the ROM to monitor the states of the battery cells 11. The microcomputer determines a remaining capacity or SOC (State of Charge) of the battery pack 10 based on the cell voltages of the battery cells 11 measured by the A/D converter 92 and the current flowing through the battery pack 10 measured by a not shown current measuring circuit. The microcomputer performs control to cause the external and internal equalizing circuits 30 and 70 to operate for equalizing the cell voltages of the respective cell batteries 11 in accordance with the determined SOC.

The microcomputer includes also a function of detecting, for each of the wires connected between the battery pack 10 and the battery voltage monitoring apparatus (that is, between the electrodes of the battery cells and the common terminals 20), a wire breakage based on the cell voltage measured when the corresponding short-circuit switch 72 of the internal equalizing circuit 70 is turned on. More specifically, the microcomputer detects a wire breakage by comparing the value of the measured cell voltage with a value of a corresponding one of the cell voltages shown in a map prepared in advance.

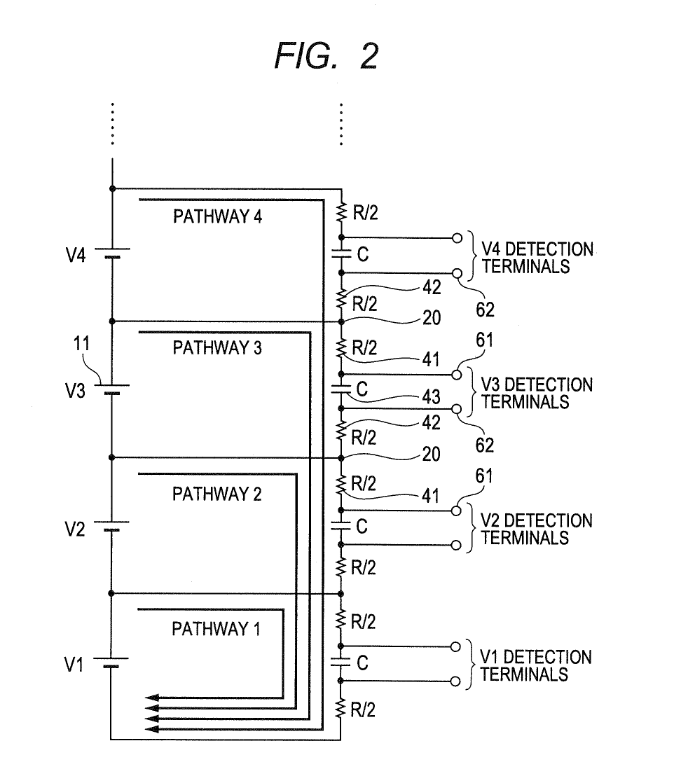

Next, the filtering characteristic of the RC filter 40 circuit of the battery voltage monitoring apparatus having the above described structure is explained with reference to FIG. 2. FIG. 2 shows four of the battery cells 11 and a part of the RC filter circuit 40 corresponding to these four battery cells 11. In FIG. 2, the external equalizing circuit 30 is omitted from illustration.

Here, the four battery cells 11 are indicated by the characters “V1”, “V2”, “V3” and “V4”, respectively, in the order from the lowest voltage side to the highest voltage side. In the following, the paired detection terminals 61 and 62 corresponding to the battery cells V1, V2, V3 and V4, respectively, are referred to as “V1 detection terminals”, “V2 detection terminals”, “V3 detection terminals” and “V4 detection terminals”, respectively. It is assumed that the resistance of each of the resistors 41 and 42 is R/2, and the capacitance of the capacitor 43 is C.

In the current pathway 1 across the electrodes of the battery cell V1, there are one resistor 41, one resistor 42 and one capacitor 43. Accordingly, the transfer function Gain of the current pathway 1 is given by the expression of Gain=1/{1+2πfRC}.

In the current pathway 2 across the electrodes of the battery cells V2 and V1, there are two resistors 41, two resistors 42 and two capacitors 43. Accordingly, the transfer function Gain of the current pathway 2 is given by the expression of Gain=1/{1+2πf·(2R)·(C/2)}.

In the current pathway 3 across the electrodes of the battery cells V3, V2 and V1, there are three resistors 41, three resistors 42 and three capacitors 43. Accordingly, the transfer function Gain of the current pathway 3 is given by the expression of Gain=1/{1+2πf·(3R)·(C/3)}.

In the current pathway 4 across the electrodes of the battery cells V4, V3, V2 and V1, there are four resistors 41, four resistors 42 and four capacitors 43. Accordingly, the transfer function Gain of the current pathway 4 is given by the expression of Gain=1/{1+2πf·(4R)·(C/4)}.

As explained above, since the resistors 41 and 42 are connected to the branches of each common terminal 20, the number of the resistors 41 and 42 increases with the increases of the number of the battery cells 11 included in the current pathway. Accordingly, variation of the cut-off frequency of the current pathway due to increase of the number of the capacitors 43 is cancelled out by the increase of the number of the resistors 41 and 42. Hence, according to this embodiment, since the cut-off frequency is the same for the respective pairs of the detection terminals 61 and 62, there is no variation in the cut-off frequency among the respective current pathways.

Incidentally, the resistance of the resistor 41 and the resistance of the resistor 41 are set to the same value of R/2 for all the battery cells. However, this setting is just an example. The resistance of the resistor 41 may be set larger than the resistance of the resistor 42 for the battery cells V2 and V3. In this case, for the battery cell V1, the resistance of the resistor 41 is set smaller than the resistance of the resistor 42.

Next, the operation to detect the cell voltage of each of the battery cells 11 performed by the battery voltage monitoring apparatus is explained. The pairs of the positive-electrode side switch 81 and the negative-electrode side switch 82 corresponding to the respective battery cells 11 are turned on sequentially in accordance with a changeover command outputted from the microcomputer. Here, it is assumed that the switches 81 and 82 corresponding to the battery cell on the lowest voltage side are turned on at first.

In this case, the detection terminal 61 corresponding to the battery cell 11 on the lowest voltage side is applied with the voltage of the positive electrode of the battery cell 11 on the lowest voltage side, and the counter-part detection terminal 62 is applied with the voltage of the negative electrode of the battery cell 11 on the lowest voltage side. In this state, when an A/D command to A/D-convert the cell voltage of the battery cell 11 on the lowest voltage side is outputted from the microcomputer to the A/D converter 92, the A/D converter 92 A/D-converts the cell voltage received from the multiplexer 80 through the differential amplifier circuit 91, and outputs the A/D-converted cell voltage to the microcomputer.

By repeating the above operation, the cell voltage is detected in the order from the battery cell 11 on the lowest voltage side to the battery cell 11 on the highest voltage side.

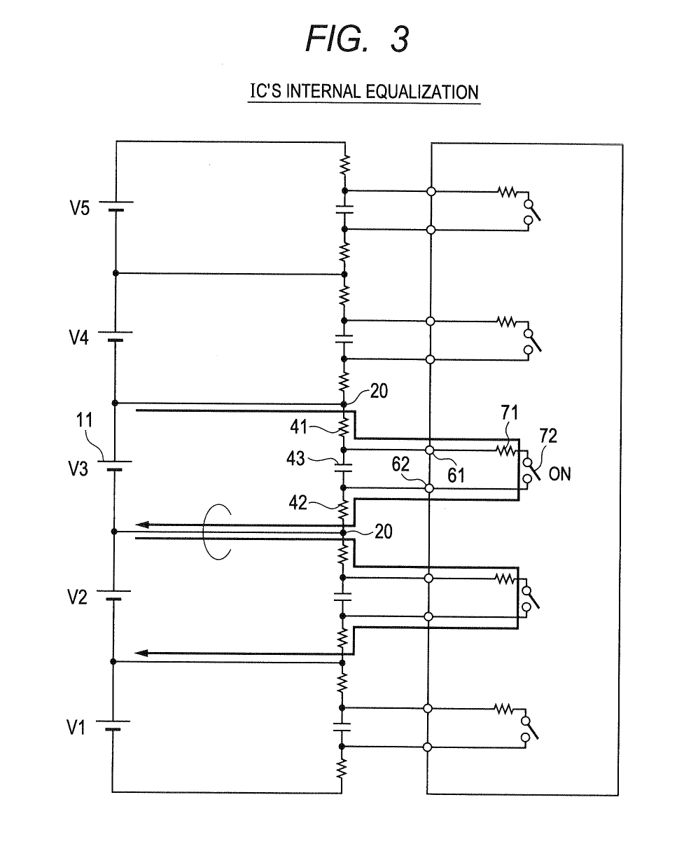

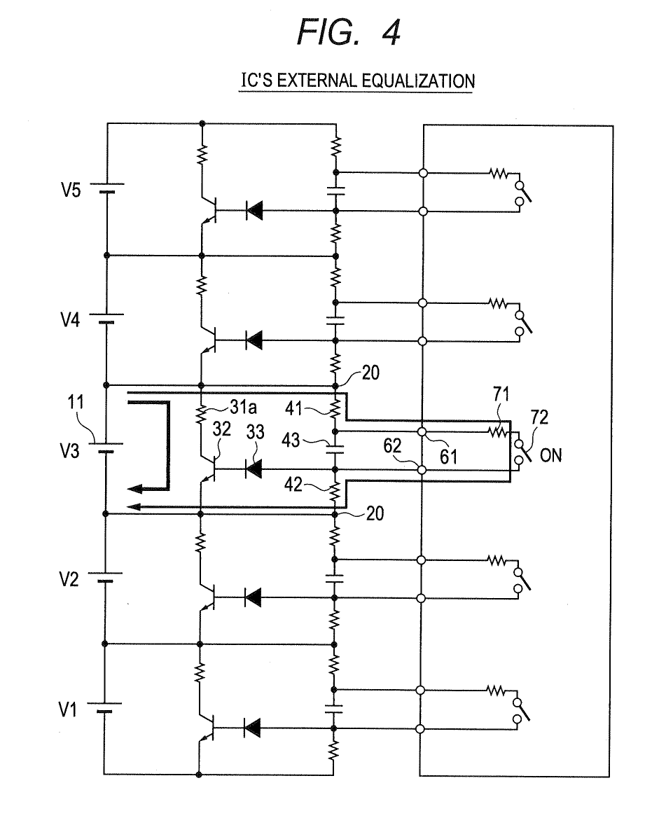

Next, the operation to equalize the cell voltages of the respective battery cells 11 performed by the battery voltage monitoring apparatus is explained with reference to FIGS. 3 and 4. The microcomputer is capable of determining which one of the battery cells 11 should be discharged based on the detection result of the cell voltages.

FIG. 3 is a diagram for explaining IC's internal equalization performed by the internal equalizing circuit 70 included in the battery voltage monitoring apparatus. In FIG. 3, the internal structures of the external equalizing circuit 30 and the monitoring IC 50 are omitted from illustration. Here, it is assumed that the short-circuit switch 72 corresponding to the battery cell V3 is turned on by the microcomputer. In this case, a discharge current from the battery cell V3 flows through the resistor 41, detection terminal 61, resistor 71, short-circuit switch 72, detection terminal 62 and resistor 42 in this order. Accordingly, the discharge current flows inside of the monitoring IC 50.

By turning on the short-circuit switches 72 corresponding to the battery cells 11 to be discharged, the cell voltages of the respective cell batteries 11 can be equalized.

If the short-circuit switch 72 corresponding to the battery cell V2 is turned on at the same time when the short-circuit switch 72 corresponding to the battery cell V3 is turned on, also a discharge current from the battery cell V2 flows. That is, discharge currents from adjacent two of the battery cells 11 flow at the same time. In this case, since the positive electrode of the battery cell V2 and the negative electrode of the battery cell V3 are connected to the same common terminal 20, and the wire connected to this common terminal 20 is interposed with no resistor, the discharge currents can be prevented from being varied by a resistor effect although the short-circuit switches 72 across different pairs of the detection terminals 61 and 62 corresponding to the adjacent two battery cells 11 are turned on at the same time.

FIG. 4 is a diagram for explaining IC's external equalization performed by the external equalizing circuit 30 included in the battery voltage monitoring apparatus. In FIG. 4, the resistors 31b and 31c are omitted from illustration.

As explained above, the internal equalizing circuit 70 equalizes the cell voltages by causing a discharge current to flow inside the IC 50. However, it is not possible to cause a large current from flowing inside the IC 50. To cope with this, in this embodiment, as shown in FIG. 4, the anode of the diode 33 is connected to the path through which the discharge current flows so that when the short-circuit switch 72 corresponding to the battery cell V3 is turned on and the internal equalizing circuit 70 operates, a current flows into the base of the transistor 32 through the diode 33 causing the transistor 32 to turn on. Accordingly, it is possible to cause a current larger than the discharge current flowing inside the monitoring IC 50 to flow through the battery cell 11 as a discharge current by way of the resistor 31a and the transistor 32.

Of course, the discharge current is not varied by a resistor effect when the external equalizing circuit 30 operates, because the wire connected between the node between the battery cells V2 and V3 and the common terminal 20 is interposed with no resistor.

As explained above, by causing the internal equalizing circuit 70 to operate, that is, by passing a current to the detection terminal 62, the external equalizing circuit 30 starts to operate naturally due to change of the voltage of the detection terminal 62. By the operations of these equalizing circuits, the cell voltages of the respective battery cells 11 are equalized. The equalizing discharge operation described above is for the battery cells V2 and V3. However, the other battery cells can be equalized by the same operation as above.

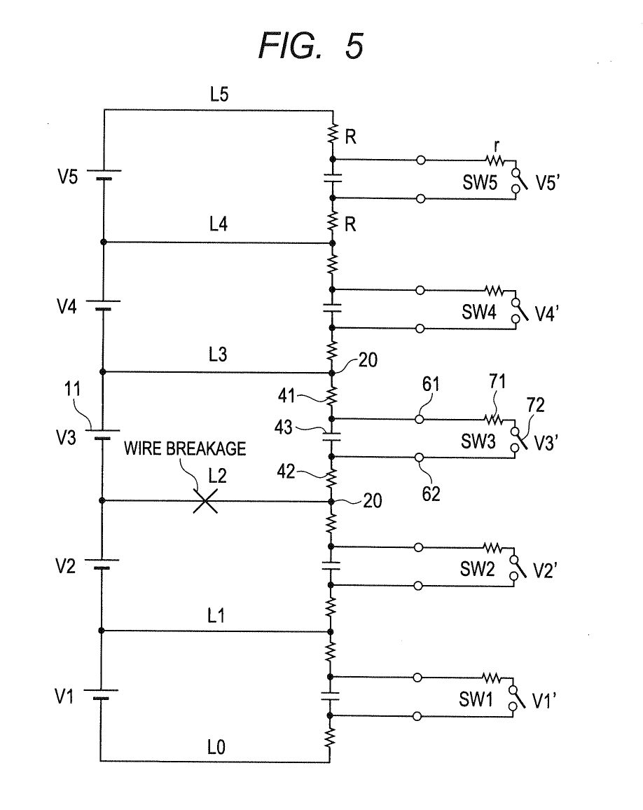

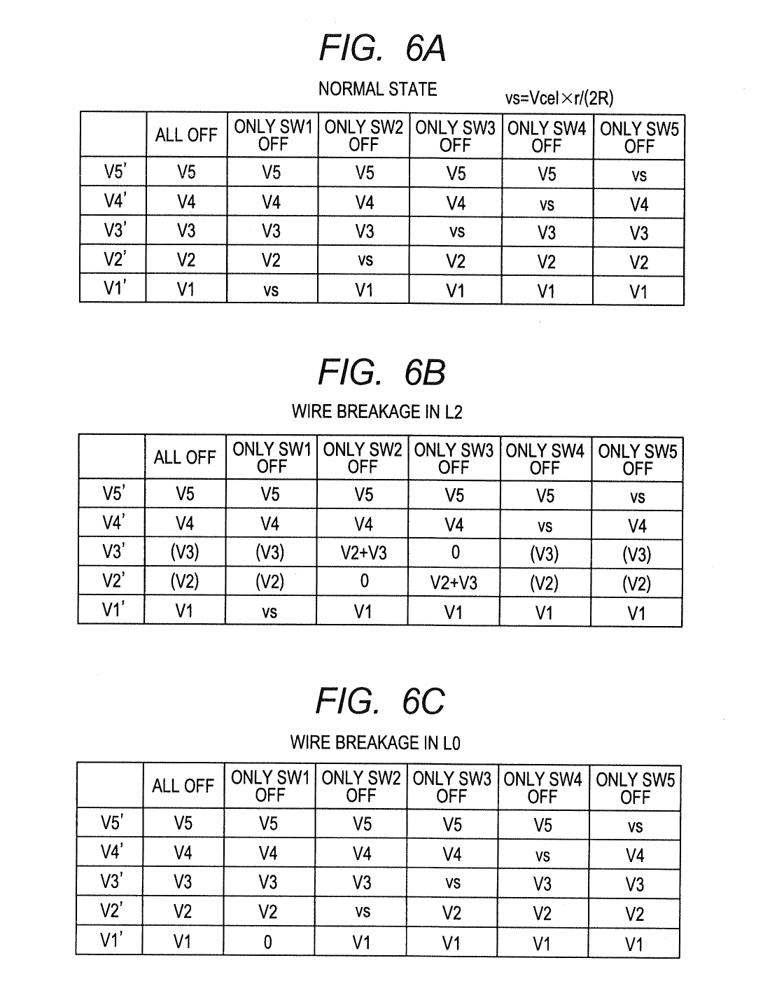

Next, the operation to detect a breakage in the wires connected between the battery pack 10 and the battery voltage monitoring apparatus performed by the battery voltage monitoring apparatus is explained with reference to FIGS. 5 and 6A to 6C. This wire breakage detection operation is performed in accordance with a program stored in the microcomputer.

FIG. 5, which shows the RC filter circuit 40 and the internal equalizing circuit 70, is for explaining the principle of the wire breakage detection operation. In FIG. 5, the internal structures of the external equalizing circuit 30 and the monitoring IC 50 are omitted from illustration.

Here, the wire connected between the negative electrode of the battery cell V1 and the resistor 42 is indicated by the characters “L0”, and the wires respectively connected between the positive electrodes and the corresponding resistors 42 are indicated by the characters, “L1”, “L2”, “L3”, “L4” and “L5”, respectively, in the order from the battery cells V1 to V5.

The short-circuit switches 72 corresponding to the battery cells V1 to V5, respectively, are indicated by the characters “SW1”, “SW2”, SW3″, “SW4” and “SW5”, respectively. It is assumed that the resistance of the resistors 71 connected to the corresponding short-circuit switches 72 is r, and the voltages across the pairs of the detection terminals 61 and 62 corresponding to the battery cells V1 to V5 are indicated by the characters “V1”, “V2′”, “V3′”, “V4′” and “V5′”, respectively. Here, the cell voltages of the battery cells V1 to V5 are indicated by V1 to V5, respectively. Accordingly, the voltage V1′ is equal to V1 in the normal state.

It is assumed that the resistances of the resistor 41 and the resistor 42 are R. The resistance r of the resistor 71 is set sufficiently smaller than the resistances of the resistor 41 and the resistor 42.

FIG. 6A is a table showing the cell voltages when there is no wire breakage. FIG. 6B is a table showing the cell voltages when there is a wire breakage in the wire L2 shown in FIG. 5. FIG. 6C is a table showing the cell voltages when there is a wire breakage in the wire L0 shown in FIG. 5.

When there is no wire breakage in the wires connected between the battery cells V1 to V5 and the RC filter circuit 40, the cell voltages of the battery cells V1 to V5 are as shown in the table of FIG. 6A.

To detect the cell voltage of one of the battery cells, the corresponding short circuit-switch 72 is turned on. For example, when only the switch SW1 corresponding to the battery cell V1 is turned on, the voltage V1′ across the corresponding pair of the detection terminals 61 and 62 is detected to be “vs” equal to the voltage drop across the resistor 71. Here, when the cell voltage is Vcel, vs=Vcel×r/(2R+r).

Likewise, when only the switch SW2 corresponding to the battery cell V2 is turned on, the voltage V2′ across the corresponding pair of the detection terminals 61 and 62 is detected to be vs. The above is the same for the other battery cells V3 to V5. As explained above, in the normal state where there is no wire breakage, the voltage across the detection terminals 61 and 62 is detected to be vs when any one of the short-circuit switch 72 is turned on.

Next, it is assumed that the wire L2 connected between the positive electrode of the battery cell V2 and the corresponding common terminal 20 is broken. In this case, since the cell voltage is not applied across the detection terminals 61 and 62 when only the switch SW2 corresponding to the battery cell V2 is turned on, the voltage V2′ is detected to be zero as shown in the table of FIG. 6B. The microcomputer detects that the detected voltage V2′ is zero different from vs, and accordingly determines that the wire L2 is broken.

Further, when only the switch SW2 corresponding to the battery cell V2 is turned on, since the detection terminals 61 and 62 corresponding to the battery cell V3 are applied with V2 and V3, respectively, the voltage V3′ is detected to be V2+V3 as shown in the table of FIG. 6B. Since the voltage V3″ is detected to be V2+V3 different from V3 which the voltage V3′ should be in the normal state as shown in the table of FIG. 6A, the microcomputer determines that the wire L2 is broken.

Likewise, when only the switch SW3 corresponding to the battery cell V3 is turned on, the voltage V3′ is detected to be zero, and the voltage V2′ is detected to be V2+V3. The microcomputer detects that the wire L2 is broken based on that the values of the detected voltages V2′ and V3′ are different from the values which they should take in the normal state.

Incidentally, when the wire L2 is broken, since the voltages V2′ and V3′ may not be detected correctly, they are put in parentheses such as (V2) or (V3) in the table of FIG. 6B.

If the wire L0 on the lowest voltage side is broken, the voltage V1′ is detected to be zero when only the switch SW1 is turned on, as shown in FIG. 6C. Accordingly, the microcomputer determines that the wire L0 is broken based on that the detected voltage V1 is 0 and not vs.

As explained above, by operating the short-circuit switches 72, it is possible not only to equalize the dell voltages but also to detect breakage of the wires connected between the battery pack 10 and the RC filter circuit 40. The wire breakage operation described above is for the wires L0 and L2, however, it is a matter of course that wire breakage of the other wires can be detected by the same operation as above.

As explained above, the first embodiment of the invention includes, as a noise countermeasure, the RC filter circuit 40 having the structure in which, for each of the battery cells 11, the common terminal 20 is branched into two branches connected with the resistor 41 and the resistor 42, respectively.

Accordingly, since no resistor is present as an RC filter component between the battery pack 10 and the RC filter circuit 40, it is possible to increase, for each current pathway across n series-connected battery cells 11, the number of the resistors 41 and 42 with the increase of the number of the battery cells 11. Hence, for each of the current pathways, the number of the capacitors and the number of the resistors 41 and 42 are cancelled out with each other, variation in cut-off frequency among the respective current pathways can be reduced.

### Second Embodiment

Next, a second embodiment of the invention is described focusing on the difference with the first embodiment. The second embodiment differs from the first embodiment in the circuit structures of the external equalizing circuit 30 and the internal equalizing circuit 70.

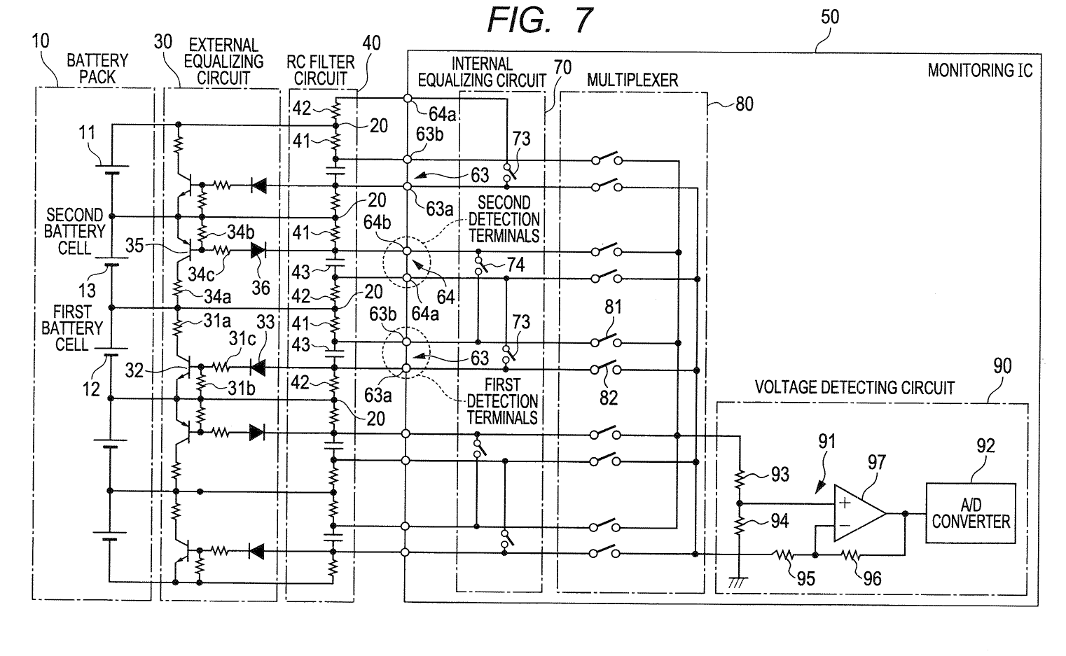

FIG. 7 is a diagram showing the overall structure of a battery voltage monitoring system including a battery voltage monitoring apparatus according to the second embodiment of the invention. As shown in FIG. 7, the structure of the RC filter circuit 40, and the structures of the multiplexer 80 and the voltage detecting circuit 90 included in the monitoring IC 50 are the same as those of the first embodiment.

In the following description, of each adjacent two battery cells 11, the one on the lower voltage side is referred to as the first battery cell 12, and the one on the higher voltage side is referred to as the second battery cell 13. The paired detection terminals 61 and 62 for detecting the cell voltage of the first battery cell 12 are collectively referred to as the first detection terminals 63, and the paired detection terminals 61 and 62 for detecting the cell voltage of the second battery cell 13 are collectively referred to as the second detection terminals 64.

In this embodiment, the external equalizing circuit 30 includes, for each first battery cell 12, the resistors 31a, 31b and 31c, the NPN transistor 32 and the diode 33. Further, the external equalizing circuit 30 includes, for each second battery cell 13, resistors 34a, 34b and 34c, a PNP transistor 35 and a diode 36.

The resistor 34a is connected at one end thereof to the negative electrode of the second battery cell 13, and connected to the collector of the transistor 35 at the other end thereof. The emitter of the transistor 35 is connected to the positive electrode of the second battery cell 13. The resistor 34b is connected between the base and emitter of the transistor 35. The resistor 34c and the diode 36 are connected in series between the base of the transistor 35 and a corresponding one of the nodes provided in the RC filter circuit 40. More specifically, the anode of the diode 36 is connected to the resistor 34c, and the cathode of the diode 36 is connected to the connection node between the resistor 41 and the capacitor 43. In this embodiment, when a current is drawn from the base of the transistor 35 through the diode 36 to turn on the transistor 35, a discharge current from the second battery cell 13 flows through the transistor 35 and the resistor 34a.

The internal equalizing circuit 70 includes a first short-circuit switch 73 and a second short-circuit switch 74. The first short-circuit switch 73 is for making an electrical connection or short-circuit between one of the first detection terminals 63 on the lower voltage side (referred to as “the lower-voltage side terminal 63a” hereinafter) and one of the second detection terminals 64 on the lower voltage side (referred to as “the lower-voltage side terminal 64a” hereinafter) to short-circuit the first battery cell 12. The second short-circuit switch 74 is for making an electrical connection between the other of the first detection terminals 63 on the higher voltage side (referred to as “the higher-voltage side terminal 63b” hereinafter) and the other of the second detection terminals 64 on the higher voltage side (referred to as “the higher-voltage side terminal 64h” hereinafter) to short-circuit the second battery cell 13.

Incidentally, as many as necessary of the pairs of the first and second battery cells 12 and 13 are connected in series. In this embodiment, since the number of the battery cells 11 constituting the battery pack 10 is five, the battery cell 11 on the highest voltage side is the first battery cell 12.

Accordingly, as shown in FIG. 7, the common terminal 20 electrically connected to the positive terminal of the first battery cell 11 on the highest voltage side branches into two branches connected with the resistor 41 and the resistor 42, respectively. The resistor 42 is connected to the corresponding lower-voltage side terminal 64a provided in the monitoring IC 50. The first short-circuit switch 73 is provided for making an electrical connection between this lower-voltage side terminal 64a and the lower-voltage side terminal 63a corresponding to the first battery cell 12 on the highest voltage side to short-circuit the first battery cell 12 on the highest voltage side.

Incidentally, the battery cell 11 on the lowest voltage side may be the second battery cell 13. In this case, the battery cell 11 on the highest side 11 is the second battery cell 13.

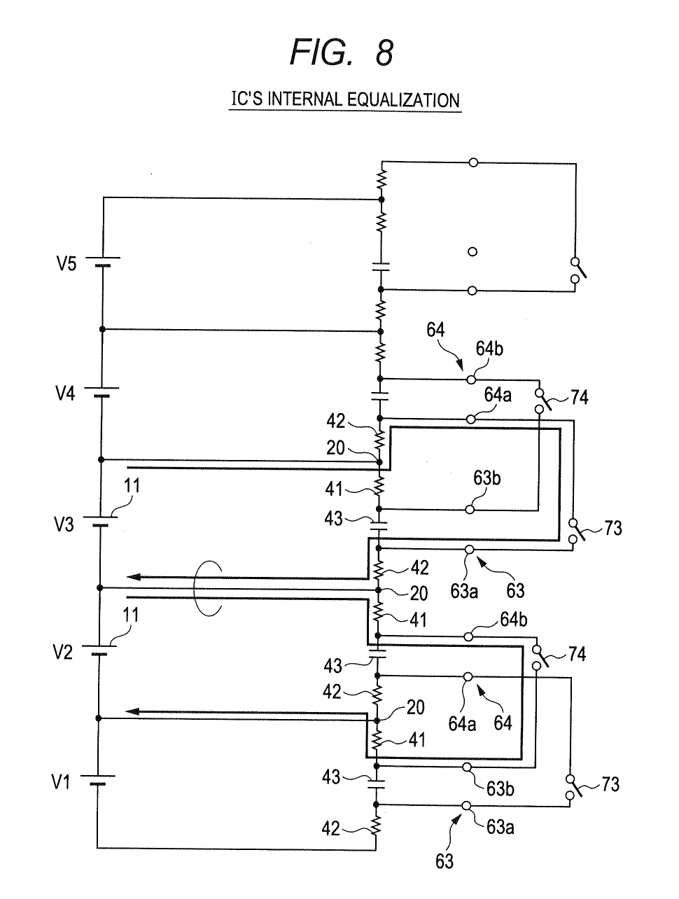

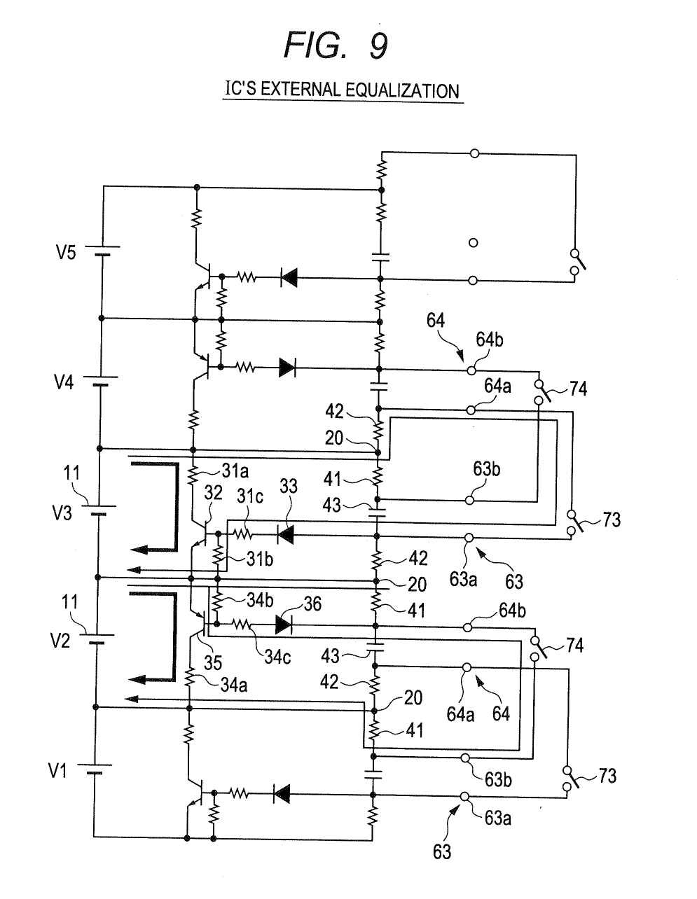

Next, the operation to equalize the cell voltages of the respective battery cells 11 performed by the battery voltage monitoring apparatus of this embodiment is explained with reference to FIGS. 8 and 9.

FIG. 8 is a diagram for explaining IC's internal equalization performed by the internal equalizing circuit 70 included in the battery voltage monitoring apparatus. In FIG. 8, the internal structures of the external equalizing circuit 30 and the monitoring IC 50 are omitted from illustration. Here, it is assumed that the first short-circuit switch 73 connected to the lower-voltage side terminal 63a corresponding to the battery cell V3 (the first battery cell 12) is turned on. In this case, a discharge current from the battery cell V3 flows through the current path including the resistor 42 corresponding to the battery cell V4, the lower-voltage side terminal 64a corresponding to the battery cell V4, the first short-circuit switch 73, the lower-voltage side terminal 63a corresponding to the battery cell V3 and the resistor 42 corresponding to the battery cell V3. As a result, the cell voltage of the cell battery V3 is equalized to those of the other battery cells.

Further, if the second short-circuit switch 74 connected to the higher-voltage side terminal 64b corresponding to the battery cell V2 (the second battery cell 13) is turned on together with the first short-circuit switch 73 corresponding to the battery cell V3, a discharge current from the battery cell V2 flows through the current path including the resistor 41 corresponding to the battery cell V2, the higher-voltage side terminal 64b corresponding to the battery cell V2, the second short-circuit switch 74, the higher-voltage side terminal 63b corresponding to the battery cell V1 and the resistor 42 corresponding to the battery cell V1.

At this time, since the wire connected between the common terminal 20 and the battery cells V2 and V3 is interposed with no resistor, the discharge currents from the adjacent battery cells V2 and V3 can be prevented from being varied by a resistor effect.

FIG. 9 is a diagram for explaining IC's external equalization performed by the external equalizing circuit 30 included in the battery voltage monitoring apparatus. In FIG. 9, the internal structure of the monitoring IC 50 is omitted from illustration. Like in the first embodiment, the external equalizing circuit 30 enables passing a large discharge current which the internal equalizing circuit 70 cannot pass, and the internal equalizing circuit 70 operates to equalize the cell voltages of the battery cells V2 and V3.

As explained above, when a discharge current flows from the battery cell V2 to the higher-voltage side terminal 64b corresponding to this battery cell V2, a current flows to the diode 36 electrically connected to this higher-voltage side terminal 64b, as a result of which the base voltage of the transistor 35 is lowered causing the transistor 35 to turn on. Hence, it is possible to cause a current larger than the discharge current flowing inside the monitoring IC 50 to flow through battery cell V2 as a discharge current by way of the transistor 35 and the resistor 34a.

Also, when a discharge current flows from the battery cell V3 to the higher-voltage side terminal 64b corresponding to this battery cell V3, a current flows to the diode 33, as a result of which the transistor 32 is turned on as with the case of the first embodiment. Hence, it is possible to cause a current larger than the discharge current flowing inside the monitoring IC to flow through the battery cell V3 by way of the resistor 31a and the transistor 32. As explained above, by passing a current to the higher-voltage side terminal 64b of the second detection terminals 64, the external equalizing circuit 30 starts to operate.

Incidentally, since the wire connected between the node between the battery cells V2 and V3 and the common terminal 20 is interposed with no resistor, the discharge currents are not varied by a resistor effect when the external equalizing circuit 30 operates. The explanation of the equalizing discharge operation described above is for the battery cells V2 and V3. However, the other battery cells can be equalized by the same operation as above.

As explained above, the internal equalizing circuit 70 can be formed by connecting the lower-voltage side terminals 63a and 64a of the first and the second detection terminals 63 and 64 to the first short-circuit switch 73, and connecting the higher-voltage side terminals 63b and 64b of the first and the second detection terminals 63 and 64 to the second short-circuit switch 74.

### Other Embodiments

It is a matter of course that various modifications can be made to the above described embodiments.

For example, the monitoring IC 50 may be replaced by an appropriate discrete circuit. As the transistor 35 of the external equalizing circuit 30 of the second embodiment, an NPN transistor may be used instead of a PNP transistor.

In the above embodiments, the resistors 41 and the resistor 42 have the same resistance. However, they may have different resistances.

In the above embodiments, the external equalizing circuit 30 is provided in the battery monitoring apparatus. However, the external equalizing circuit 30 may not be provided in the battery monitoring apparatus if it is unnecessary to perform the equalizing discharge using the external equalizing circuit 30.

In the first embodiment, the diode 33 of the external equalizing circuit 30 is electrically connected to the detection terminal 62 to operate by the current flowing to the detection terminal 62. However, the external equalizing circuit 30 may be connected to any one of the detection terminals 61 and 62, if the external equalizing circuit 30 is configured to operate by the current flowing to any of the detection terminals 61 and 62.

In the second embodiment, the lower-voltage side terminal 63a of the first detection terminals 63 corresponding to the first battery cell 12 is electrically connected to the diode 33 of the external equalizing circuit 30, and the higher-voltage side terminal 64b of the second detection terminals 64 corresponding to the second battery cell 13 is electrically connected to the diode 36 of the external equalizing circuit 30. However, the external equalizing circuit 30 may be connected to anyone of the detection terminals 63a and 63b of the first detection terminals 63 corresponding to the first battery cell 12, and to any one of the detection terminals 64a and 64b of the second detection terminals 64 corresponding to the second battery cell 13, if the external equalizing circuit 30 is configured to operate by the current flowing to any of the detection terminals 63a, 63b, 64a and 64b. For example, the higher-voltage side terminal 63b of the first detection terminals 63 corresponding to the first battery cell 12 may be connected to the diode 33. In the external equalizing circuit 30 of the second embodiment, the transistor 32 corresponding to the first battery cell 12 is an NPN transistor, and the transistor 35 corresponding to the second battery cell 13 is a PNP transistor. However, all the transistors of the external equalizing circuit 30 may be NPN transistors. In the first and second embodiments, the transistors 32 and 35 are bipolar transistors. However they may be MOSFETs.

The above explained preferred embodiments are exemplary of the invention of the present application which is described solely by the claims appended below. It should be understood that modifications of the preferred embodiments may be made as would occur to one of skill in the art.

What is claimed is:

1. A battery voltage monitoring apparatus comprising:
pairs of positive side and negative side detection terminals provided respectively corresponding to positive and negative electrodes of battery cells connected in series to form a battery pack;
an RC filter circuit interposed between the positive and negative electrodes of the battery cells and the pairs of the positive side and negative side detection terminals; and
a detection means for detecting a cell voltage of each of the battery cells applied across a corresponding one of the pairs of the positive side and negative side detection terminals,
wherein
for each adjacent two of the battery cells, the positive electrode of the battery cell on the higher voltage side and the negative electrode of the battery cell on the lower voltage side are commonly connected to a common terminal provided in the RC filter circuit,
the common terminal is branched into a first branch connected to one end of a first resistor as a component of the RC filter circuit and a second branch connected to one end of a second resistor as a component of the RC filter circuit, the first resistor being connected to a corresponding one of the positive side detection terminals at the other end thereof, the second resistor being connected to a corresponding one of the negative side detection terminals at the other end thereof, and
a capacitor is connected across a corresponding one of the pairs of the positive side and negative side detection terminals as a component of the RC filter circuit.

2. The battery voltage monitoring apparatus according to claim 1, wherein, for each of the pairs of the positive side and negative side detection terminals, a short-circuit switch is provided for making a short circuit between the positive side and negative side detection terminals.

3. The battery voltage monitoring apparatus according to claim 2, further comprising an external equalizing circuit including, for each of the battery cells, a discharge means electrically connected to one of the positive side and negative side detection terminals, and configured to cause a discharge current to flow through the battery cell in response to a change of a voltage of the one of the positive side and negative side detection terminals.

4. The battery voltage monitoring apparatus according to claim 1, wherein, for each adjacent two of the battery cells, when the battery cell on the lower voltage side is referred to as a first battery cell, the battery cell on the higher voltage side is referred to as a second battery cell, a corresponding one of the pairs of the positive side and negative side detection terminals for detecting the cell voltage of the first battery cell is referred to as first detection terminals, and a corresponding one of the pairs of the positive side and negative side detection terminals for detecting the cell voltage of the second battery cell is referred to as second detection terminals,
the battery voltage monitoring apparatus further comprises a first short-circuit switch for making a short circuit between one of the first detection terminals on the lower voltage side and one of the second detection terminals on the lower voltage side, and a second short-circuit switch for making a short circuit between the other of the first detection terminals on the higher voltage side and the other of the second detection terminals on the higher voltage side.

5. The battery voltage monitoring apparatus according to claim 4, further comprising an external equalizing circuit including, for each of the battery cells, a discharge means electrically connected to one of the first detection terminals and one of the second detection terminals, and configured to cause a discharge current to flow through the battery cell in response to a change of a voltage of the one of the first detection terminals or the one of the second detection terminals.
